(19) United States
(12) Patent Application Publication
(10) Pub. No.: US 2026/0204514 A1
(43) Pub. Date: Jul. 16, 2026

(54) MULTI-CHARGED PARTICLE BEAM WRITING METHOD, MULTI-CHARGED PARTICLE BEAM WRITING APPARATUS AND COMPUTER READABLE RECORDING MEDIUM

(71) Applicant: NuFlare Technology, Inc., Yokohama-shi (JP)

(72) Inventors: Tetsushi KOKUBO, Kawasaki-shi (JP); Hiroshi MATSUMOTO, Yokohama-shi (JP)

(73) Assignee: NuFlare Technology, Inc., Yokohama-shi (JP)

(21) Appl. No.: 19/392,528

(22) Filed: Nov. 18, 2025

(30) Foreign Application Priority Data
Jan. 6, 2025 (JP) 2025-001925

(51) Int. Cl. H01J 37/317; H01J 37/304

(52) U.S. Cl. CPC H01J 37/3177; H01J 37/3045; H01J 2237/0435; H01J 2237/31764

(57) ABSTRACT

In one embodiment, a multi-charged particle beam writing method includes a step of setting, in a writing region of a sample, a plurality of writing grids obtained by shifting a plurality of ideal grids by a shift amount with anisotropy, the plurality of ideal grids being arranged in a lattice pattern with an equal pitch, and a step of writing a pattern on the sample by irradiating the plurality of writing grids with a multi-beam.

### CROSS REFERENCE TO RELATED APPLICATION

This application is based upon and claims benefit of priority from the Japanese Patent Application No. 2025-1925, filed on Jan. 6, 2025, the entire contents of which are incorporated herein by reference.

### FIELD

The present invention relates to a multi-charged particle beam writing method, a multi-charged particle beam writing apparatus and a computer readable recording medium.

### BACKGROUND

As LSI circuits are increasing in density, the required linewidths of circuits included in semiconductor devices become finer year by year. To form a desired circuit pattern on a semiconductor device, a method is employed in which a high-precision original pattern formed on quartz is transferred to a wafer in a reduced manner by using a reduced-projection exposure apparatus. High-precision original patterns are written on a photomask by an electron beam writing apparatus.

A writing apparatus using multiple beams enables irradiation with a large number of beams at once as compared with writing with a single electron beam, and thereby significantly improve throughput. Examples of such multi-beam writing apparatuses include a multi-beam writing apparatus using a blanking aperture array substrate (blanking plate). In such a multi-beam writing apparatus, for example, an electron beam emitted from a single electron gun passes through a shaping aperture array substrate having multiple apertures, thus forming multiple beams (multiple electron beams). The blanking aperture array substrate is disposed downstream of the shaping aperture array substrate. The blanking aperture array substrate includes pairs of electrodes for individually deflecting the beams, and has an aperture for beam passage between each pair of electrodes. One of the paired electrodes (blanker) is held at ground potential, and the other electrode is switched between the ground potential and a potential other than the ground potential, thus achieving blanking deflection of an electron beam that is to pass through the blanker. The multi-beam writing apparatus includes an optical column configured such that an electron beam deflected by the blanker is blocked and switched to an OFF state and an electron beam that is not deflected is applied as an ON-state beam to a sample.

In the multi-beam writing apparatus, the beam characteristics in X direction and Y direction may be different. For example, as illustrated in FIG. 20, an edge extending in X direction may be lower in resolution than an edge extending in Y direction, and an edge portion may appear blurry. Or, as illustrated in FIG. 21, the LER (Line Edge Roughness) of an edge extending in Y direction may be greater than the LER of an edge extending in X direction.

The anisotropy of the beam characteristics affects a writing result, and causes a problem in that the writing accuracy may be degraded.

### BRIEF DESCRIPTION OF THE DRAWINGS

FIG. 1 is a schematic view of a multi-charged particle beam writing apparatus according to an embodiment of the present invention.

FIG. 2 is a plan view of a shaping aperture array substrate.

FIG. 3 is a schematic configuration view of a blanking aperture array substrate.

FIG. 4 is a conceptual view for explaining an example of a writing operation.

FIG. 5 is a view illustrating an example of an irradiation region of a multi-beam and writing target pixels.

FIG. 6 is a view for explaining step and repeat writing.

FIG. 7 is a view illustrating an example of shift of writing grids.

FIG. 8 is a view illustrating an example of written patterns.

FIG. 9 is a view illustrating an example of shift of writing grids.

FIG. 10 is a view illustrating an example of shift of writing grids.

FIG. 11 is a flowchart illustrating a writing method according to the embodiment.

FIG. 12 is a view illustrating an example of shift of writing grids.

FIG. 13 is a view illustrating an example of shift of writing grids.

FIG. 14 is a view illustrating an example of shift of writing grids.

FIGS. 15A and 15B are views illustrating examples of shift of writing grids.

FIG. 16 is a view illustrating an example of shift of writing grids.

FIG. 17A is a view illustrating an example of an isotropic shift, and

FIG. 17B is a view illustrating an example of an anisotropic shift.

FIG. 18 is a view illustrating an example of shift of writing grids.

FIG. 19 is a view illustrating an example of shift of writing grids.

FIG. 20 is a view illustrating an example of written patterns.

FIG. 21 is a view illustrating an example of written patterns.

### DETAILED DESCRIPTION

In one embodiment, a multi-charged particle beam writing method includes a step of setting, in a writing region of a sample, a plurality of writing grids obtained by shifting a plurality of ideal grids by a shift amount with anisotropy, the plurality of ideal grids being arranged in a lattice pattern with an equal pitch, and a step of writing a pattern on the sample by irradiating the plurality of writing grids with a multi-beam.

In the following embodiments, a configuration using an electron beam as an example of a charged particle beam will be described. However, the charged particle beam is not limited to an electron beam, and may also be a beam using charged particles such as an ion beam.

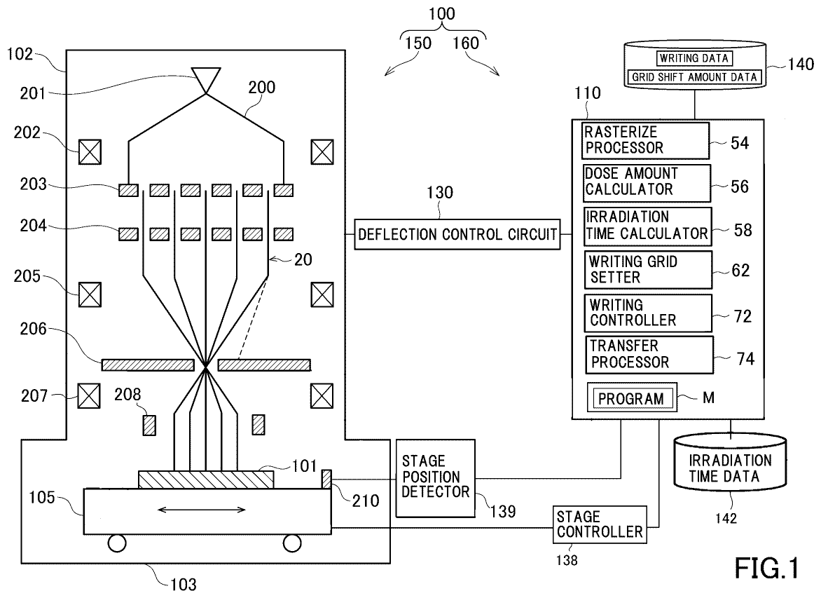

FIG. 1 is a schematic diagram showing a writing apparatus according to the embodiment. As illustrated in FIG. 1, a writing apparatus 100 includes a writer 150 and a controller 160. The writing apparatus 100 is an example of a charged particle multi-beam writing apparatus. The writer 150 includes an electron optical column 102 and a writing chamber 103. In the electron optical column 102, an electron source 201, an illumination lens 202, a shaping aperture array substrate 203, a blanking aperture array substrate 204, a reduction lens 205, a limiting aperture substrate 206, an objective lens 207 and a deflector 208 are disposed.

An XY stage 105 is disposed in the writing chamber 103. A sample (substrate) 101 serving as a writing target is disposed on the XY stage 105. The upper surface of the sample 101 is coated with a resist to be exposed by an electron beam. For example, the sample 101 is a mask blank for producing a photomask. A mirror 210 for stage position measurement is further disposed on the XY stage 105.

The controller 160 includes a control computer 110, a deflection control circuit 130, a stage controller 138, a stage position detector 139, and storage units 140 and 142.

Writing data is inputted to the storage unit 140 from the outside, and stored therein. In the writing data, information on a plurality of figure patterns to be written is defined. Specifically, for each figure pattern, the figure code, coordinates, and size are defined. In the writing data, other information, for example, control information on irradiation amount may be additionally defined.

In addition, grid shift amount data is input to the storage unit 140 from the outside, and stored therein. The grid shift amount data will be described later.

The position of the XY stage 105 is controlled by driving a motor (not illustrated) for each axis, which is controlled by the stage controller 138. The stage position detector 139 detects the position of the XY stage 105 by receiving light reflected from the mirror 210 based on the principle of laser interferometry.

The control computer 110 includes a rasterize processor 54, a dose amount calculator 56, an irradiation time calculator 58, a writing grid setter 62, a writing controller 72 and a transfer processor 74. Each component of the control computer 110 may be comprised of hardware such as an electric circuit, or comprised of software such as a program that executes these functions. When each component is comprised of software, it is possible to store, in a recording medium, a program implementing at least part of the functions of the control computer 110, and to cause a computer to read and execute the program. The recording medium is not limited to a detachable one such as a magnetic disk or an optical disc, and may be a fixed recording medium such as a hard disk drive or a memory. A program may be stored in a memory M in the control computer 110.

The writing operation of the writing apparatus 100 is controlled by the writing controller 72. The process of transfer of irradiation time data of each shot to the deflection control circuit 130 is controlled by the transfer processor 74.

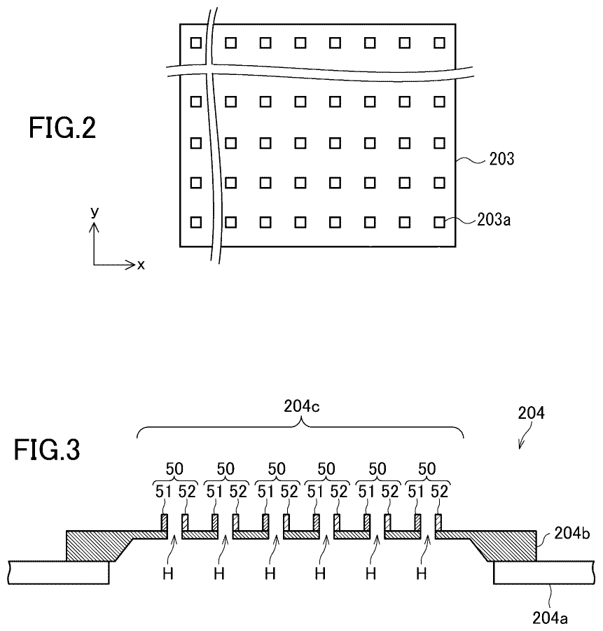

FIG. 2 is a conceptual view illustrating the configuration of the shaping aperture array substrate 203. The shaping aperture array substrate 203 is a plate-like member, and as illustrated in FIG. 2, a plurality of openings 203a are formed in the surface of the shaping aperture array substrate 203 in a vertical direction (y direction) and a horizontal direction (x direction). The shape of each opening 203a is rectangular or circular.

An electron beam 200 emitted from the electron source 201 illuminates the shaping aperture array substrate 203 by the illumination lens 202. Part of the electron beam 200 passes through the plurality of openings 203a of the shaping aperture array substrate 203, and the remaining beam is stopped by the shaping aperture array substrate 203, thus a multi-beam 20 including multiple beams is formed. The shape of various beams (individual beams) forming the multi-beam 20 conforms with the shape of the openings 203a of the shaping aperture array substrate 203, and is e.g., rectangular.

As illustrated in FIG. 3, the blanking aperture array substrate 204 includes a support stand 204a, and a semiconductor substrate 204b composed of silicon and the like provided on the support stand 204a. The central portion of the semiconductor substrate 204b is thinly scraped off from the back surface side, and processed to form a membrane region 204c with a thin film thickness. The periphery surrounding the membrane region 204c is an outer peripheral region with a thick film thickness, and the semiconductor substrate 204b is held on the support stand 204a via the back surface of the outer peripheral region. The central portion of the support stand 204a is open, and the position of the membrane region 204c is located on the open area of the support stand 204a.

In the membrane region 204c, a plurality of beam passage holes H are formed corresponding to the arrangement positions of the plurality of openings 203a of the shaping aperture array substrate 203. A blanker 50 consisting of a set of two electrodes 51, 52 forming a pair is disposed at each of the beam passage holes H, and one of beams in the multi-beam passes through between the pair of electrodes, and a passage hole H. The blanker 50 grounds one electrode 51 to maintain the ground electric potential, and switches between OFF/ON of deflection of a beam passing through each passage hole H by changing the other electrode 52 to the ground electric potential or an electric potential other than the ground electric potential. Thus, the blanker 50 performs blanking control of setting each beam in the multi-beam to one of beam-ON or beam-OFF state. The principle of the blanking control will be stated below.

When one individual beam in the multi-beam is controlled to a beam-ON state, the opposed electrodes 51, 52 of the blanker 50 are controlled at the same electric potential, and the blanker 50 does not deflect the beam passing through a passage hole H. When one individual beam is controlled to a beam-OFF state, the opposed electrodes 51, 52 of the blanker 50 are controlled at different electric potentials, and the blanker 50 deflects the beam passing through a passage hole H.

The multi-beam 20 which has passed through the blanking aperture array substrate 204 is reduced by the reduction lens 205, and travels to an opening formed in the limiting aperture substrate 206.

Each beam controlled to a beam-OFF state is deflected by the blanker 50, and passes through a trajectory deviated from the opening of the limiting aperture substrate 206, thus is blocked by the limiting aperture substrate 206. In contrast, each beam controlled to a beam-ON state is not deflected by the blanker 50, thus passes through the opening of the limiting aperture substrate 206. The trajectory of the beam controlled to a beam-ON state is adjusted by an alignment coil (not illustrated) so that the beam passes through the opening of the limiting aperture substrate 206. In this manner, an ON/OFF state of each beam in the multi-beam is controlled by combination of ON/OFF operation of deflection of the blanker 50, and blocking of the beam by the limiting aperture substrate 206. In short, blanking control is performed.

The multi-beam 20 which has passed through the limiting aperture substrate 206 is focused by the objective lens 207, and forms a pattern image on the sample 101 with a desired reduction ratio. The multi-beam is ideally arranged on the sample 101 with the pitch which is the product of the arrangement pitch of the plurality of openings 203a of the shaping aperture array substrate 203 and the above-mentioned desired reduction ratio. The beams (the entire beam-ON state beams in the multi-beam) which have passed through the limiting aperture substrate 206 are deflected by the deflector 208 in the same direction, and irradiated onto desired positions on the sample 101 with the beams focused on the surface of the sample 101.

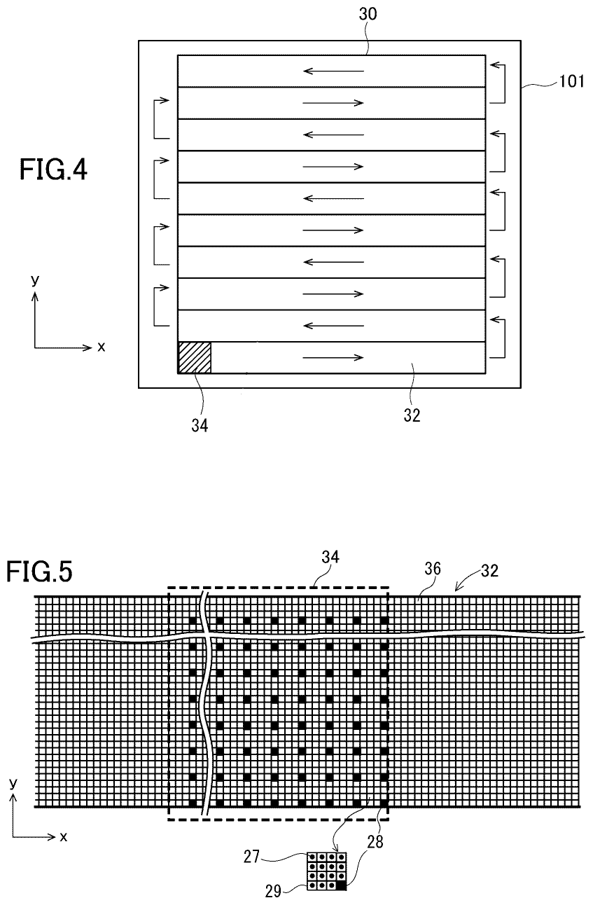

FIG. 4 is a conceptual view for explaining an example of a writing operation. As illustrated in FIG. 4, a writing region 30 of the sample 101 is virtually divided into e.g., a plurality of stripe-shaped regions 32 with a predetermined width in y direction. The example of FIG. 4 shows a case in which the writing region 30 of the sample 101 is divided into a plurality of stripe regions 32 e.g., in y direction with substantially the same width size as the size of a design irradiation region 34 (writing field) which can be irradiated with the multi-beam 20 at one time. The size of the design irradiation region 34 of the multi-beam 20 in x direction can be defined by the number of beams in x direction ×the pitch between the beams in x direction. The size of the irradiation region 34 in y direction is defined by the number of beams in y direction ×the pitch between the beams in y direction.

First, the XY stage 105 is moved, and the irradiation region 34 of the multi-beam 20 is adjusted to be located at the left end of the first stripe region 32, and writing is performed on the first stripe region 32. When writing is performed on the first stripe region 32, the XY stage 105 is moved in e.g., −x direction, thus writing is performed relatively in x direction. After the writing on the first stripe region 32 is completed, the stage position is moved by the size of the width of the stripe region 32 in −y direction.

Next, the irradiation region 34 of the multi-beam 20 is adjusted to be located at the right end of the second stripe region 32, writing is performed relatively in-x direction by moving the XY stage 105 e.g., in x direction, thus writing is performed on the second stripe region 32.

Hereinafter, writing is performed on each stripe region 32 while changing the direction alternately, thus the stage movement time can be reduced, and the writing time can be shortened. Writing may be performed on each stripe region 32 in the same direction. In one shot, a plurality of shot patterns are formed at one time by the multi-beam formed by the beam passing through the openings 203a of the shaping aperture array substrate 203, the plurality of shot patterns being at most the same in number as the openings 203a.

FIG. 5 is a view illustrating an example of an irradiation region of the multi-beam and writing target pixels. In FIG. 5, each stripe region 32 is divided into a plurality of mesh-shaped regions with the beam size of the individual beam of the multi-beam 20, or with a size smaller than the beam size. Each mesh region is a pixel 36 (a beam irradiation unit region, an irradiation position) as a writing target. FIG. 5 shows, within the irradiation region 34, a plurality of pixels 28 (irradiation positions of the beam) which can be irradiated with one shot of the multi-beam 20. The pitch between adjacent pixels 28 is the pitch between the beams in the multi-beam. One sub-irradiation region 29 (pitch cell region) is formed by a rectangular region surrounded with the size of the pitch between the beams in x, y directions. In the example of FIG. 5, the sub-irradiation region 29 comprises 4×4 pixels.

Each pixel 36 is formed with the center at a writing grid 27. Writing grids 27 (ideal grids) which are ideal correspond to the intersection points of a plurality of lattice straight lines arranged with an equal pitch. In addition, each writing grid 27 corresponds to the central position of the individual beam with which a pixel 36 is irradiated.

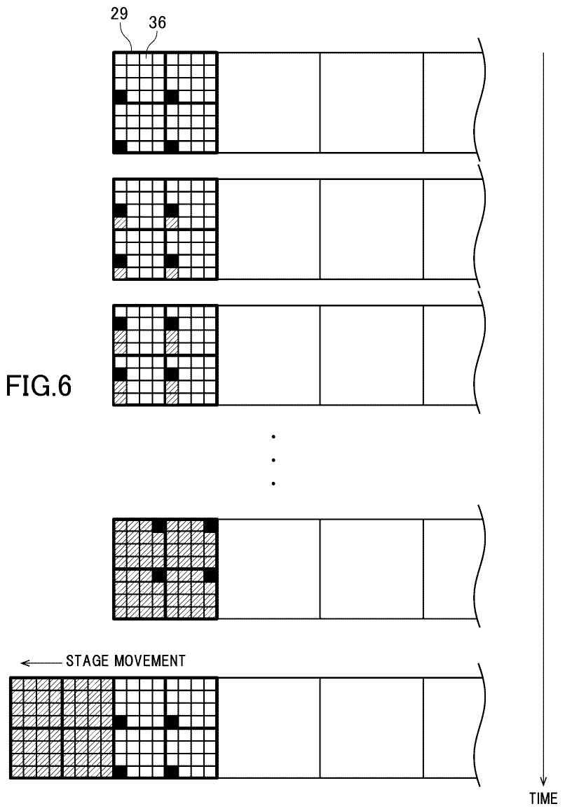

In the present embodiment, so-called step and repeat writing is performed in which with the XY stage 105 stopped, a plurality of pixels 36 in one sub-irradiation region 29 are sequentially exposed with the same individual beam. For example, as illustrated in FIG. 6, with the XY stage 105 stopped, using the deflector 208, shot is performed while shifting the irradiation position of the individual beam sequentially from the lower left pixel of each sub-irradiation region. For the purpose of illustration, FIG. 6 shows a multi-beam consisting of individual beams in 2×2 rows. When 16 shots are performed, and writing on 4×4 pixels constituting the sub-irradiation region 29 is completed, the XY stage 105 is moved to align the beam irradiation position with the writing grid of the lower left pixel of the next sub-irradiation region 29.

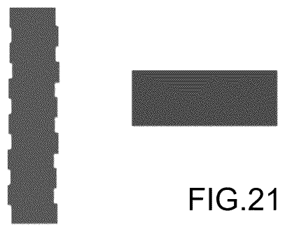

As described above, in the multi-beam writing, the beam characteristics in the X direction and Y direction differ. As illustrated in FIG. 20, the resolution in X direction may be lower than the resolution in Y direction, causing edge portion to become blurry. As illustrated in FIG. 21, the LER (edge position roughness) of the edge in Y direction may be greater than the LER of the edge in X direction. It is desirable that the difference in characteristics between the X and Y directions in the writing result be small.

Thus, in the present embodiment, ideal writing grids are shifted only in X direction (or Y direction) to obtain anisotropic writing grids with an uneven pitch, and the LER of the edge in X direction (or Y direction) or blur is intentionally increased so that the characteristics in X direction and Y direction are made approximately equal in the result of writing.

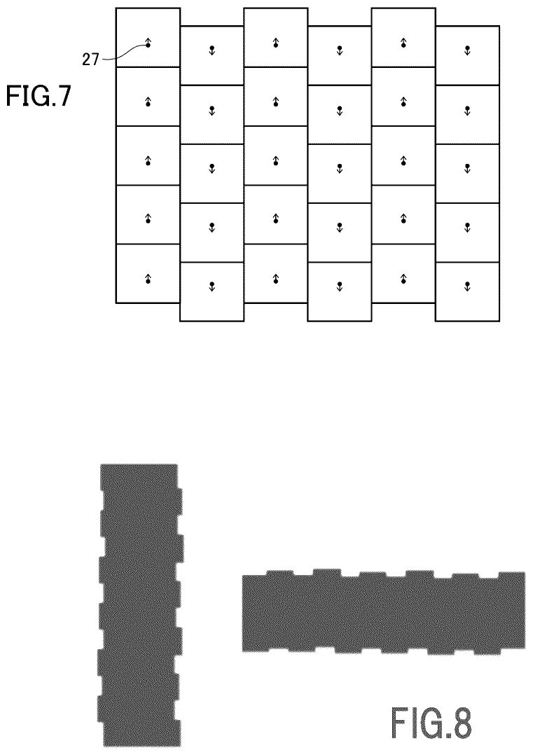

For example, when the writing apparatus 100 has characteristics such that the LER of the edge (perpendicular line) in Y direction is greater than the LER of the edge (horizontal line) in X direction, as illustrated in FIG. 7, the writing grids 27 are shifted in a perpendicular direction row by row in Y direction. For example, in the odd-numbered rows from the left in the sub-irradiation region, the writing grids 27 are shifted in an upper direction (+Y direction), and in the even-numbered rows, the writing grids 27 are shifted in a lower direction (−Y direction). Thus, as illustrated in FIG. 8, the LER of the edge in X direction in the result of writing can be intentionally aggravated, and the LER of the edge in X direction and the edge in Y direction can be made approximately equal.

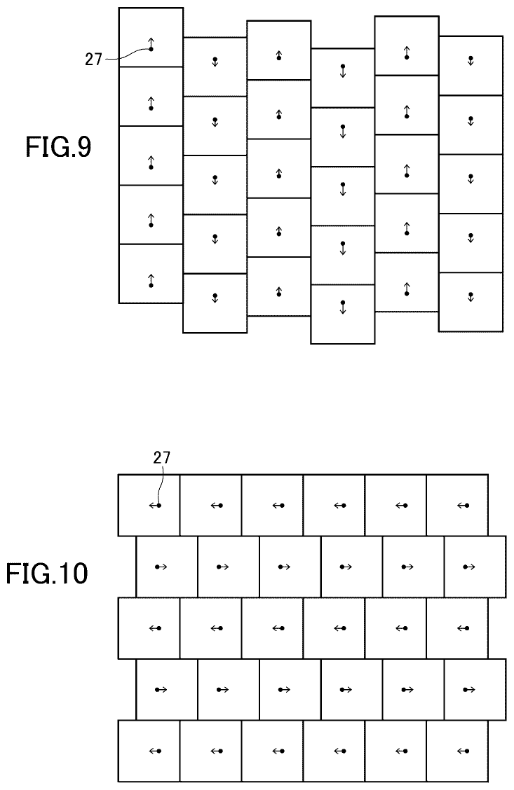

In the example illustrated in FIG. 7, the shift amount (the absolute value of the shift amount) for each row in the upper direction shift is the same as the shift amount in the lower direction shift; however, as illustrated in FIG. 9, the shift amount may vary with each row. The shift amount of each row is preferably determined so that the centroid of the entire writing grids in the sub-irradiation region is not displaced.

When the writing apparatus 100 has characteristics such that the LER of the edge in X direction is greater than the LER of the edge in Y direction, as illustrated in FIG. 10, the writing grids should be horizontally shifted for each row in X direction. For example, in the odd-numbered rows from the bottom in the sub-irradiation region, the writing grids are shifted to the left direction, and in the even-numbered rows, the writing grids are shifted to the right direction. Thus, the LER of the edge in Y direction in the result of writing can be intentionally aggravated, and the LER of the edge in X direction and the LER of the edge in Y direction can be made approximately equal.

The above-mentioned example in which ideal writing grids are shifted only in X direction (or Y direction) is a typical example of anisotropy, and more generally anisotropy includes a situation where the shift amounts in X direction and Y direction are different (for example, the absolute value average of the shift amount in X direction is different from the absolute value average of the shift amount in Y direction).

The method of determining a shift amount is not limited to a specific one; however, for example, an evaluation pattern such as a line-and-space pattern is written in advance with multiple different shift amounts, and a shift amount which gives a desired writing result can be selected, and stored in the storage unit 140 as the grid shift amount data. Alternatively, an evaluation pattern may be written without shifting the writing grids, and the shape of the individual beam may be calculated from the result of writing, and the shift amount may be determined.

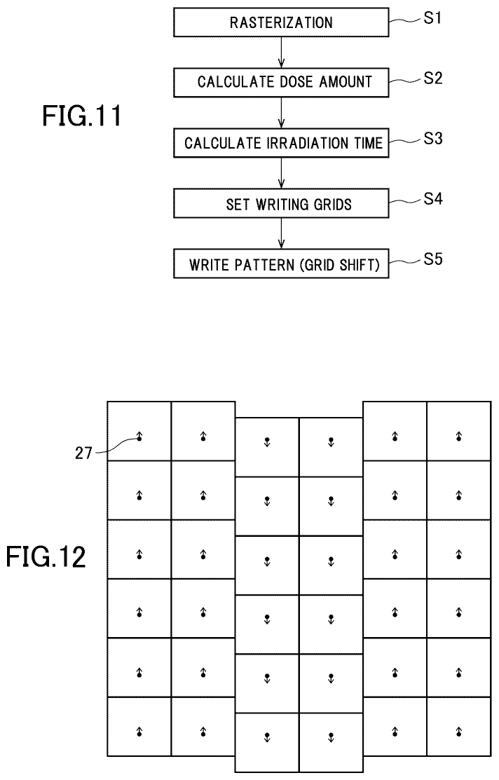

Next, a writing method according to the present embodiment will be described with reference to the flowchart illustrated in FIG. 11.

The rasterize processor 54 reads chip pattern data (writing data) from the storage unit 140, and performs rasterization (step S1). Specifically, a pattern density ρ (pattern areal density) is calculated for each pixel 36 of the ideal grid.

For each pixel 36 of the ideal grid, the dose amount calculator 56 calculates an incident irradiation amount d(x) (dose amount) for irradiating the pixel 36 (step S2). The dose amount calculator 56 first calculates a proximity effect correction irradiation amount Dp(x) for correcting the proximity effect for each proximity mesh region. An unknown proximity effect correction irradiation amount Dp(x) can be defined by a threshold value model for proximity effect correction, similar to a conventional technique which uses a backscatter coefficient η, an irradiation amount threshold value Dth of a threshold value model, a pattern areal density ρ″, and a distribution function ƒ(x). The proximity effect correction irradiation amount Dp(x) is calculated as a relative value which is normalized with standard irradiation amount Dbase of 1. It is preferable that the size of each proximity mesh region be set to approximately 1/10 the radius of influence of the proximity effect, e.g., approximately 1 μm.

For example, the incident irradiation amount d(x) may be calculated as the value obtained by multiplying the standard irradiation amount Dbase by the proximity effect correction irradiation amount Dp(x) and the pattern areal density ρ. The standard irradiation amount Dbase can, for example, be defined by Dth/(½+η). Thus, the incident irradiation amount d(x) for each pixel with the proximity effect corrected based on the layout of the plurality of figure patterns defined in the writing data can be obtained.

The dose amount calculator 56 generates a dose map consisting of elements which are the incident irradiation amounts d(x) of the pixels 36. In other words, each pixel (position) (x, y) and the incident irradiation amount d(x) of the pixel are defined in association with each other. The generated dose map is stored in the storage unit 142. The dose amount calculator 56 generates, based on the writing data (chip data), a dose map for the entirety of the writing region 30 on which a writing process is performed.

Note that when multiple writing passes are performed, a dose map is generated for each pass.

The irradiation time calculator 58 calculates an irradiation time t for each pixel 36 using the incident irradiation amount d(x) (dose amount) (step S3). The irradiation time t for each pixel 36 can be calculated by dividing the incident irradiation amount d(x) of the pixel by the current density J of the beam with which the pixel is irradiated. When the incident irradiation amount d(x) defined in the dose map is normalized with the standard irradiation amount Dbase of 1, the irradiation time t for each pixel 36 can be calculated by dividing the product of the incident irradiation amount d(x) and the standard irradiation amount Dbase by the current density J of the beam irradiating the pixel.

The writing controller 72 then rearranges the irradiation time data of each pixel 36 obtained in the shot order, and stores the irradiation time data in the storage unit 142. The transfer processor 74 transfers the irradiation time data to the deflection control circuit 130 in the shot order.

The writing grid setter 62 determines, using the grid shift amount data in the storage unit 140, the amount of shift from the ideal grids arranged in a lattice pattern with an equal pitch, and sets the plurality of writing grids 27 with the positions thereof displaced as the stripe region 32 (writing region) of the sample 101 (step S4).

Under the control of the writing controller 72, the writer 150 writes a pattern on the sample 101 so that the plurality of writing grids 27 displaced in position from the ideal grids are irradiated with the multi-beam 20 (step S5). At that time, the writer 150 irradiates, with the multi-beam 20, the plurality of writing grids 27 each displaced in position by the beam with the incident irradiation amount d(x) for each ideal grid based on the data rasterize-processed by a plurality of ideal grids. The deflector 208 deflects the multi-beam 20 for each shot based on the shift amount (positional deviation amount) for the grids. Thus, the position displaced from an ideal grid by the grid shift amount defined in each writing grid 27 is irradiated with the beam for the writing grid.

In the above embodiment, an example has been described in which a grid row in the sub-irradiation region is shifted for each row in a vertical direction or a horizontal direction alternately, but may be shifted once for multiple rows in a vertical direction or a horizontal direction alternately. FIG. 12 illustrates an example in which the writing grids 27 are shifted once for two rows in an upper or lower direction alternately. Thus, the period of irregularity (unevenness) of the edge can be changed.

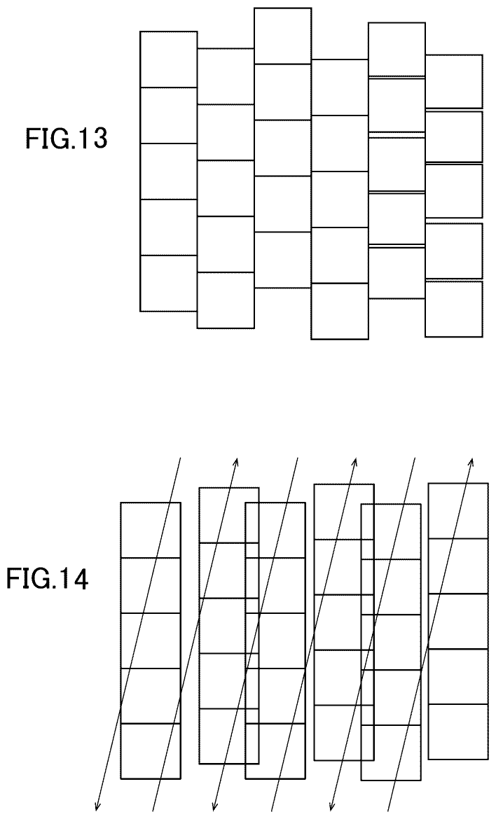

In the above embodiment, the shift amounts for the plurality of writing grids in the same grid row are the same; however, as illustrated in FIG. 13, the writing grids in the same grid row may have the same shift direction and different shift amounts.

The shift direction of the writing grids is not limited to X direction, Y direction, and may be a diagonal direction forming a predetermined angle with respect to the X or Y direction. For example, as illustrated in FIG. 14, the writing grids may be shifted row by row in a lower left or upper right direction alternately.

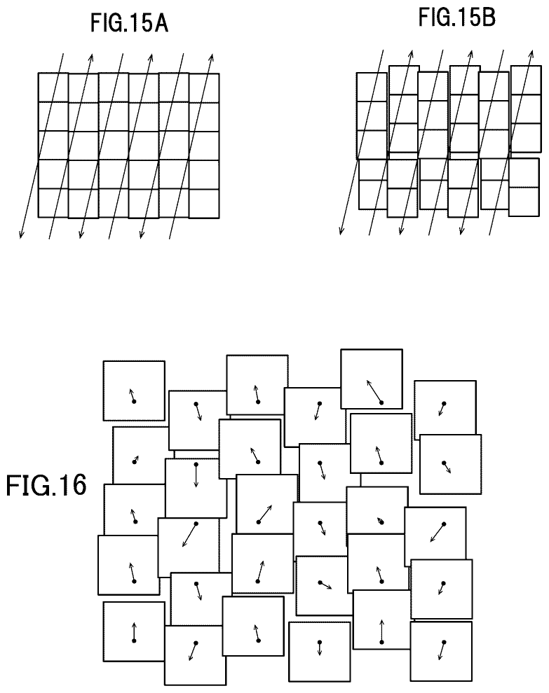

As illustrated in FIGS. 15A and 15B, diagonal lines in the shift direction are drawn at regular intervals, and according to the direction of a line which passes through the pixel at the center of each writing grid, the writing grid may be shifted. In the example illustrated in FIGS. 15A and 15B, the 1st and 2nd writing grids from the bottom of the left end row are shifted to the upper right, and the 3rd to 5th writing grids from the bottom are shifted to the lower left.

As illustrated in FIG. 16, the plurality of writing grids in the sub-irradiation region may be provided with anisotropy overall greater in either one of X direction or Y direction so that irregular shift amounts may be applied to the writing grids. For example, as mentioned below, shift amount Shift_X in X direction, and shift amount Shift_Y in Y direction are calculated by a random function, and coefficients Kx, Ky to be multiplied may be adjusted. For example, the absolute value average of the shift amount in X direction is made larger than the absolute value average of the shift amount in Y direction.
Shift_X=Kx*rand( )
Shift_Y=Ky*rand( )

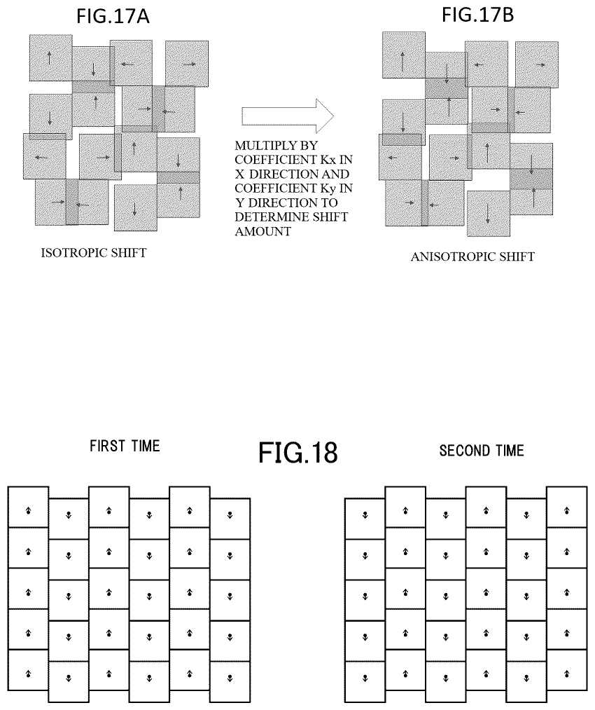

FIG. 17A shows a pattern to isotropically shift writing grids in +X direction, −X direction, +Y direction, −Y direction periodically. In this manner, a preset shift pattern is held in the storage unit 140, and as illustrated in FIG. 17B, shift amounts with anisotropy may be applied by multiplying the shift pattern by X direction shift amount coefficient Kx and Y direction shift amount coefficient Ky.

When multi-writing is performed, shift amounts in opposite directions may be applied to the first time (the first pass) writing and the second time (the second pass) writing. For example, as illustrated in FIG. 18, for the first time writing, in the odd-numbered rows from the left in the sub-irradiation region, the writing grids are shifted in an upper direction, and in the even-numbered rows, the writing grids are shifted in a lower direction. For the second time writing, in the odd-numbered rows from the left in the sub-irradiation region, the writing grids are shifted in a lower direction, and in the even-numbered rows, the writing grids are shifted in an upper direction. With slightly deviated irradiation in a vertical direction based on the same data, an effect (anisotropy) is achieved which is equivalent to the one when the beam shape becomes vertically long. In addition, irregularity of the edge can be reduced, thus anisotropy with higher quality can be achieved.

Also, in the shift in a diagonal direction, a (reversed) shift amount in opposite direction may be applied for each of passes of multi-writing.

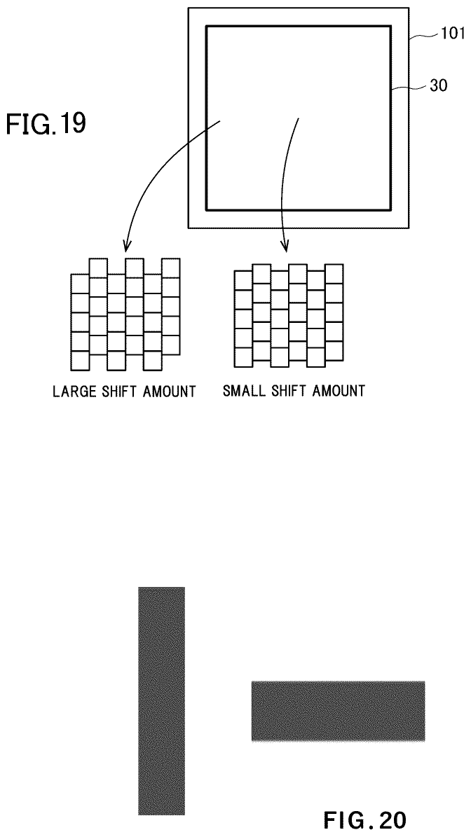

The shift amount for the writing grids may be changed according to the position in the writing region 30. For example, as illustrated in FIG. 19, the shift amount for the edge area of the writing region 30 is made larger than the shift amount for the central portion of the writing region 30. Thus, it is possible to cope with characteristics with dependence on the position in the writing region 30.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A multi-charged particle beam writing method comprising:
a step of setting, in a writing region of a sample, a plurality of writing grids obtained by shifting a plurality of ideal grids by a shift amount with anisotropy, the plurality of ideal grids being arranged in a lattice pattern with an equal pitch; and
a step of writing a pattern on the sample by irradiating the plurality of writing grids with a multi-beam.

2. The multi-charged particle beam writing method according to claim 1, further comprising
a step of deflecting the multi-beam for each shot based on a positional deviation amount of the plurality of writing grids.

3. The multi-charged particle beam writing method according to claim 1,
wherein an absolute value average of the shift amount in a first direction is different from an absolute value average of the shift amount in a second direction perpendicular to the first direction.

4. The multi-charged particle beam writing method according to claim 3,
wherein writing is performed on stripe regions obtained by dividing the writing region with a predetermined width in the first direction, and
wherein, with a stage carrying the sample stopped, a plurality of pixels in each sub-irradiation region surrounded by a pitch size between beams on a sample surface are sequentially exposed with a same individual beam, and after exposing the plurality of pixels, the stage is moved in the second direction.

5. The multi-charged particle beam writing method according to claim 3,
wherein the plurality of ideal grids are shifted in only one of the first direction and the second direction.

6. The multi-charged particle beam writing method according to claim 5,
wherein the plurality of ideal grids are shifted row by row in the first direction or the second direction.

7. The multi-charged particle beam writing method according to claim 4,
wherein the plurality of ideal grids are shifted in a diagonal direction different from the first direction and the second direction.

8. The multi-charged particle beam writing method according to claim 2,
wherein the shift amount is determined by multiplying a predetermined isotropic shift pattern by a coefficient for the first direction and a coefficient for the second direction.

9. The multi-charged particle beam writing method according to claim 1,
wherein the shift amount is reversed for each multiple writing pass.

10. The multi-charged particle beam writing method according to claim 1,
wherein the shift amount is changed according to a position within the writing region.

11. A multi-charged particle beam writing apparatus comprising:
a writing grid setter that sets, in a writing region of a sample, a plurality of writing grids obtained by shifting a plurality of ideal grids by a shift amount with anisotropy, the plurality of ideal grids being arranged in a lattice pattern with an equal pitch; and
a writer that writes a pattern on the sample using a multi-beam so that the plurality of writing grids are irradiated.

12. A non-transitory computer readable recording medium storing a program causing a computer to execute a process comprising:
setting, in a writing region of a sample, a plurality of writing grids obtained by shifting a plurality of ideal grids by a shift amount with anisotropy, the plurality of ideal grids being arranged in a lattice pattern with an equal pitch; and
writing a pattern on the sample using a multi-beam by controlling a writer so that the plurality of writing grids are irradiated.
